(19) United States
(12) Patent Application Publication
(10) Pub. No.: US 2014/0226294 A1
(43) Pub. Date: Aug. 14, 2014

(54) DISPLAY DEVICE

(71) Applicants: Kazuho Sakurai, Osaka (JP); Toshiya Mizuno, Osaka (JP); Isshin Kinugawa, Osaka (JP)

(72) Inventors: Kazuho Sakurai, Osaka (JP); Toshiya Mizuno, Osaka (JP); Isshin Kinugawa, Osaka (JP)

(73) Assignee: PANASONIC CORPORATION, Kadoma-shi, Osaka (JP)

(21) Appl. No.: 14/342,415

(22) PCT Filed: Jan. 12, 2012
(86) PCT No.: PCT/JP2012/000143

§ 371 Date: Mar. 3, 2014

(51) Int. Cl. H05K 5/02

(52) U.S. Cl. CPC H05K 5/0247
USPC 361/752

(57) ABSTRACT

A display system in which no space for housing an external terminal device is created on a board is provided. This display device includes: a display panel; a board; a back cover which covers the board at least partially and which has an opening; and a slot structure which is arranged inside the opening and into which an external terminal device is inserted. The slot structure includes a guide which holds the external terminal device inserted so that the external terminal device defines a predetermined angle with respect to the board and a terminal which electrically connects the external terminal device to the board.

### TECHNICAL FIELD

The present invention relates to a display device to which an external terminal device is attached, and more particularly relates to a mechanism for a display device to which an external terminal device is attached.

### BACKGROUND ART

Some of conventional display devices can have their functions extended by connecting an external terminal device thereto. Examples of such external terminal devices to be connected to display devices include cards with an IC to decode an encrypted broadcast signal, storage media, and communications modules.

For example, Patent Document No. 1 discloses a display device which has an internal board with a slot through which an external terminal device can be inserted.

### CITATION LIST

### Patent Literature

Patent Document No. 1: Japanese Laid-Open Patent Publication No. 2007-250926

### SUMMARY OF INVENTION

### Technical Problem

According to the conventional technologies, however, either such a slot through which an external terminal device is inserted or the external terminal device itself will take up so much space on the board that it is difficult to design the display device easily or cut down the cost, which is a problem.

More specifically, according to the conventional technologies, most of the external terminal device is supposed to be housed in the display device, and therefore, a space (such as a slot) for housing the external terminal device should be secured on the board of the display device.

Basically, however, it is the user to decide whether or not he or she would like to use an external terminal device. That is why even if such a space for housing an external terminal device is created on the board, no external terminal devices could be used at all in some cases. In such a situation, the space created on the board for external terminal devices would be useless. Therefore, if such a space which has been created on the board for external terminal devices could be eliminated, then the design process would be done more easily and the cost could be cut down.

The present inventors perfected our invention in order to overcome such a problem by providing a display system in which no such space for housing an external terminal device is created on the board of a display device.

### Solution to Problem

A display device according to an embodiment of the present invention includes: a display panel; a board; a back cover which covers the board at least partially and which has an opening; and a slot structure which is arranged inside the opening and into which an external terminal device is inserted. The slot structure includes a guide which holds the external terminal device inserted so that the external terminal device defines a predetermined angle with respect to the board and a terminal which electrically connects the external terminal device to the board.

The guide may regulate the angle of insertion of the external terminal device so that the external terminal device is inserted at the predetermined angle with respect to the board.

If the guide has a length of 40 mm or more, the guide may hold the external terminal device so that the external terminal device defines an angle of 5 to 9 degrees with respect to the board.

The bottom surface of the slot structure may partially cover the board.

The slot structure may have a box shape which is formed by the bottom surface of the slot structure and side surfaces that cover the slot structure entirely except an insertion slot into which the external terminal device is inserted.

The slot structure may cover the periphery of the opening at least partially.

The slot structure may be comprised of a plurality of members including a first member with the terminal and a second member with the guide.

The second member may have connecting portions for mounting the second member onto the board.

An end of the connecting portions may be made of an elastically deformable material, and the second member may be mounted onto the board by elastically deforming the respective ends of the connecting portions and fitting the ends into holes or notches that have been cut through the board.

The back cover may have a first plane and a second plane which is arranged so as to be raised with respect to the first plane. The opening may have been cut through the second plane. And when the guide holds the external terminal device, the external terminal device may be held so as to be housed within the second plane.

A terminal receiving a signal from an external device may be arranged in a step portion which is located between the first and second planes.

### Advantageous Effects of Invention

In a display device according to the present invention, the back cover of the display device has a slot to hold an external terminal device obliquely with respect to the display device. Thus, there is no need to create a space corresponding to the area of the external terminal device on the board of the display device but just a space for connecting the slot needs to be secured. Since the space that is ordinarily created for an external terminal device can be eliminated from the board, the design process can get done more easily and the cost can be cut down.

### BRIEF DESCRIPTION OF DRAWINGS

FIG. 1A A front view of a display device 100.

FIG. 1B A rear view of the display device 100.

FIG. 1C A side view of the display device 100.

FIG. 2 Illustrates an exemplary appearance of an external terminal device 200.

FIG. 3A A rear view of a display device 100 according to an embodiment of the present invention.

FIG. 3B A perspective view illustrating how a connecting slot 103 and surrounding members look when the external terminal device 200 is inserted into the display device 100.

FIG. 3C A side view of the display device 100 into which the external terminal device 200 has been inserted.

FIG. 4 A cross-sectional view of the display device 100 into which the external terminal device 200 has been inserted.

FIG. 5 An exploded perspective view of the connecting slot 103 and other surrounding members.

FIG. 6 (a) is an enlarged perspective view of a first member 402 and (b), (c), (d) and (e) are respectively a left side view, a top view, a right side view, and a bottom view of the first member 402.

FIG. 7 (a) is an enlarged perspective view of a second member 403 and (b), (c), (d) and (e) are respectively a left side view, a top view, a right side view, and a bottom view of the second member 403.

### DESCRIPTION OF EMBODIMENTS

Hereinafter, an embodiment of a display device according to the present invention will be described with reference to the accompanying drawings.

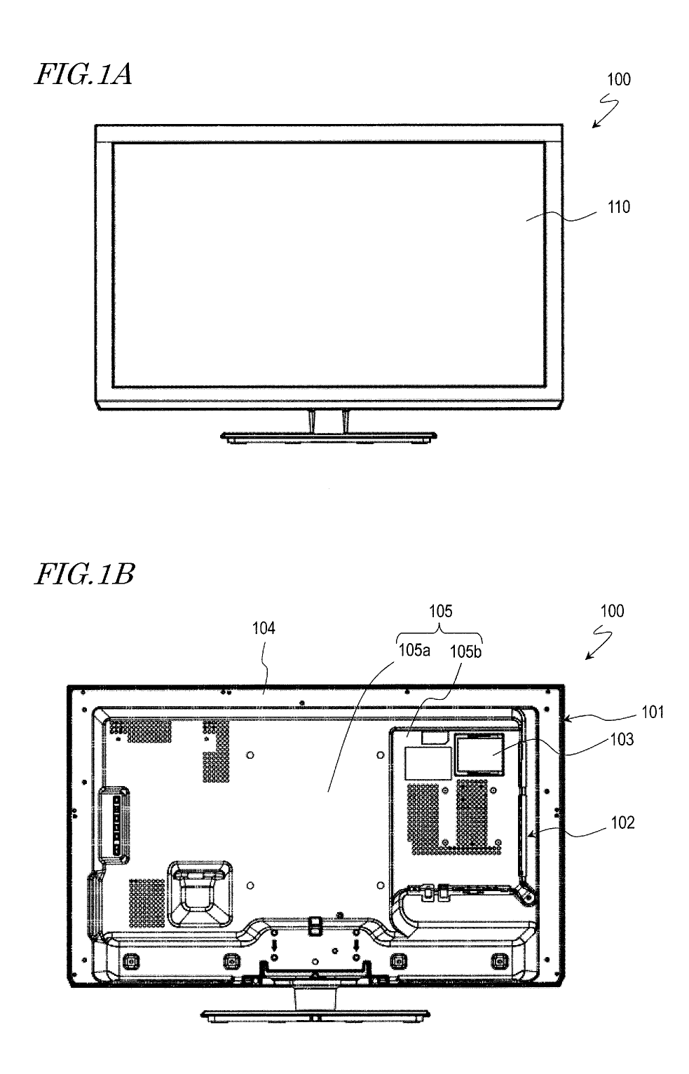

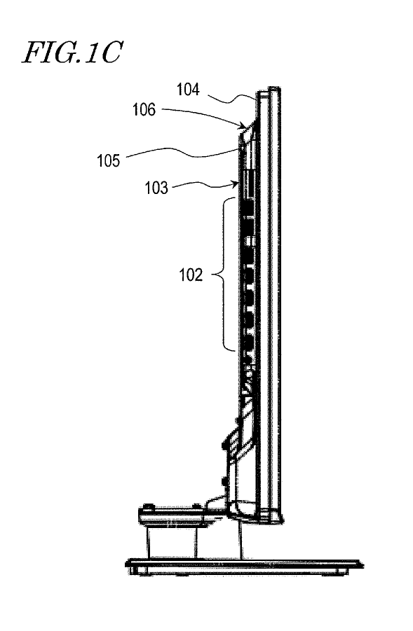

FIGS. 1A to 1C illustrate the appearance of a display device 100 as an embodiment of the present invention.

FIG. 1A is a front view of the display device 100. The display device 100 includes a display panel 110. The display device 100 gets a video signal generated based on a broadcast signal or a storage medium in a board (not shown), which is built in the display device 100, and displays the video signal on the display panel 110.

FIG. 1B is a rear view of the display device 100. The display device 100 includes a back cover 101, a group of terminals 102, and a connecting slot 103.

The back cover 101 covers not only the rear surface of the display panel 110 but also the board either entirely or partially. The back cover may be made of molded plastic or a metallic material.

The group of terminals 102 is a set of terminals which receive signals from external devices. Examples of terminals that may form the group of terminals 102 include an HDMI terminal, an SD card slot, a YUV component terminal, a CVBS terminal, a broadcast signal receiving tuner terminal, a headphone terminal that outputs an audio signal, an optical output terminal, a USB terminal that communicates bidirectionally with an externally connected device, and a LAN terminal.

The connecting slot 103 is arranged in an opening, which has been cut through the back cover 101, in order to receive an external terminal device inserted. A (group of) terminal(s) to get electrically connected to an external terminal device is arranged at the deepest end of the connecting slot 103, and is connected to the board of the display device 100.

It should be noted that the term “slot” originally means a “hole” or a “space”. In this description, however, the “slot” refers to a combination of a hole to which an external terminal device is inserted and a structure to hold the external terminal device. That is why the slot will be sometimes referred to herein as a “slot structure” in that sense.

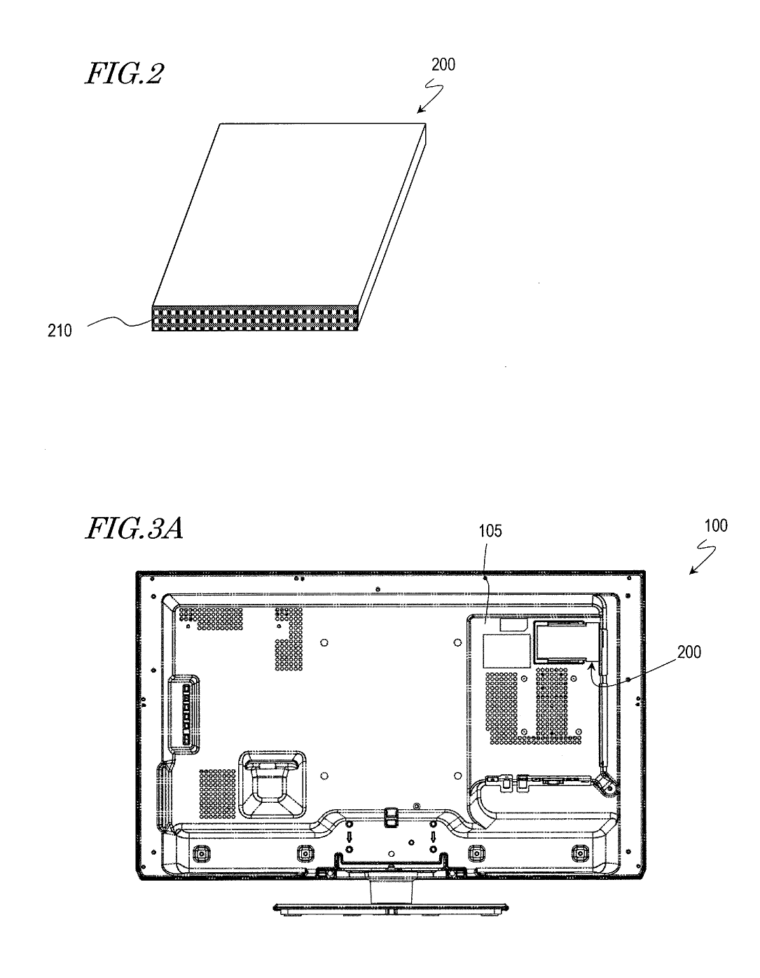

Examples of external terminal devices to be connected to the connecting slot 103 include a card compliant with the PCMCIA standard. FIG. 2 illustrates an exemplary appearance of the external terminal device 200, which includes a group of terminals 210 to be connected to the connecting slot 103. The group of terminals 210 is electrically conductive with internal circuits in the external terminal device 200 through wiring (not shown).

In this embodiment, the external terminal device 200 is supposed to be a CI card that needs to be used for a digital broadcast DVB-T in the European district. Examples of the circuits built in the external terminal device 200 (CI card) include an IC chip to decode an encrypted broadcast signal and a memory to store the decoded information.

It should be noted that the external terminal device 200 does not have to be a CI card. Alternatively, the external terminal device 200 may also be an IC card to descramble a scrambled signal which is attached to a CATV set top box (STB) or an IC card for use to authenticate a device which is legitimately authorized to receive a digital broadcast.

Now take a look at FIG. 1B again.

The connecting slot 103 includes a guide to guide the external terminal device inserted to a predetermined direction and a terminal to electrically connect the external terminal device and the internal board together. The guide is also used to hold the external terminal device inserted in that position. The structure of the connecting slot 103 will be described in further detail later.

The back cover 101 has a first plane 104 and a second plane 105. When the display panel 110 shown in FIG. 1A is viewed straight on, the second plane 105 is located deeper (i.e., in the direction coming out of the paper) than the first plane 104. That is to say, there is a level difference between the first and second planes 104 and 105. It should be noted that as long as there is any plane at a different level from the first plane 104, that plane will be referred to herein as a second plane 105. That is why both of the planes 105a and 105b shown in FIG. 1B are second planes 105. The first and second planes 104 and 105 do not have to be planes in a strict sense.

FIG. 1C is a side view of the display device 100. It can be seen that there is a step portion 106 between the first and second planes 104 and 105. That is to say, the back cover 101 of this embodiment has the first and second planes 104 and 105 and a step portion 106 to create a level difference between them.

Part of the group of terminals 102 is arranged in the step portion 106. Also, as will be described later, the connecting slot 103 is provided by taking advantage of the step portion 106.

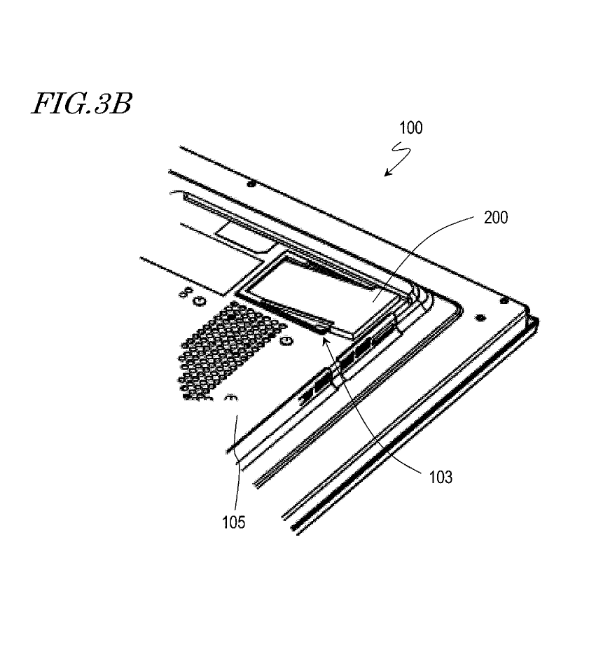

FIGS. 3A to 3C illustrate how an external terminal device has been inserted into the display device of this embodiment.

FIG. 3A is a rear view of the display device 100 of this embodiment.

A broadcast signal that has been received by the display device 100 is decoded based on the decoding information that is stored in the external terminal device 200.

As shown in FIG. 3A, in this embodiment, the external terminal device 200 inserted into the connecting slot 103 is located almost entirely within the second plane 105. That is to say, the external terminal device 200 inserted into the connecting slot 103 does not project out of the second plane 105. As there is no space created between the first plane 104 and the external terminal device 200, the chances of touching the external terminal device 200 by mistake can be reduced even if the user of this display device 100 has happened to have his or her hand inserted into the space due to the presence of the step portion 106.

In the embodiment described above, the back cover 101 is supposed to have the first and second planes 104 and 105. However, this is just an example of the present invention. Alternatively, the back cover 101 may also have a flat surface. Even so, the connecting slot 103 may be arranged so that the external terminal device 200 is entirely located on the back cover 101. In that case, as the external terminal device 200 will not protrude outward from the front side of the display device 100, the chances that the user of the display device 100 will touch the external terminal device 200 by mistake can be reduced. In addition, the place to set up the display device 100 in will no longer be restricted by the external terminal device 200. For example, if the external terminal device 200 protruded outward from the frame of the display panel 110 of this display device 100 when the display panel 110 is viewed straight on, then it would be difficult to set up the display device 100 beside the wall to which the external terminal device 200 protrudes. On the other hand, if the external terminal device 200 can be entirely arranged on the back cover 101, then the display device 100 can be set up beside a wall in any direction. That is to say, in that case, no matter whether the external terminal device 200 has been inserted or not, there is no need for the user to change the place to set up the display device 100 in.

FIG. 3B is a perspective view illustrating how the connecting slot 103 and surrounding members look when the external terminal device 200 is inserted into the display device 100. As can be seen from FIG. 3B, almost all of the external terminal device 200 is housed within the second plane 105.

FIG. 3C is a side view of the display device 100 into which the external terminal device 200 has been inserted. When the display panel 110 is viewed straight on, the external terminal device 200 is held at a deeper position than a part of the group of terminals 102. Then, it is possible to prevent the external terminal device 200 from interfering with the user who is connecting a cable or anything else to the group of terminals 102.

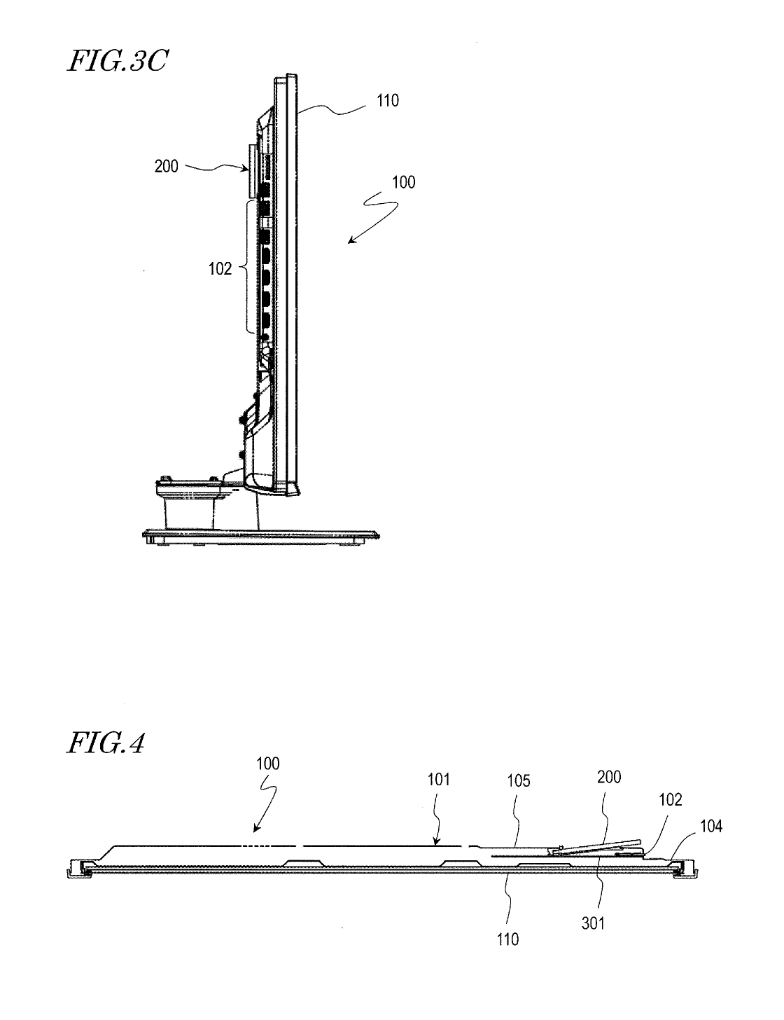

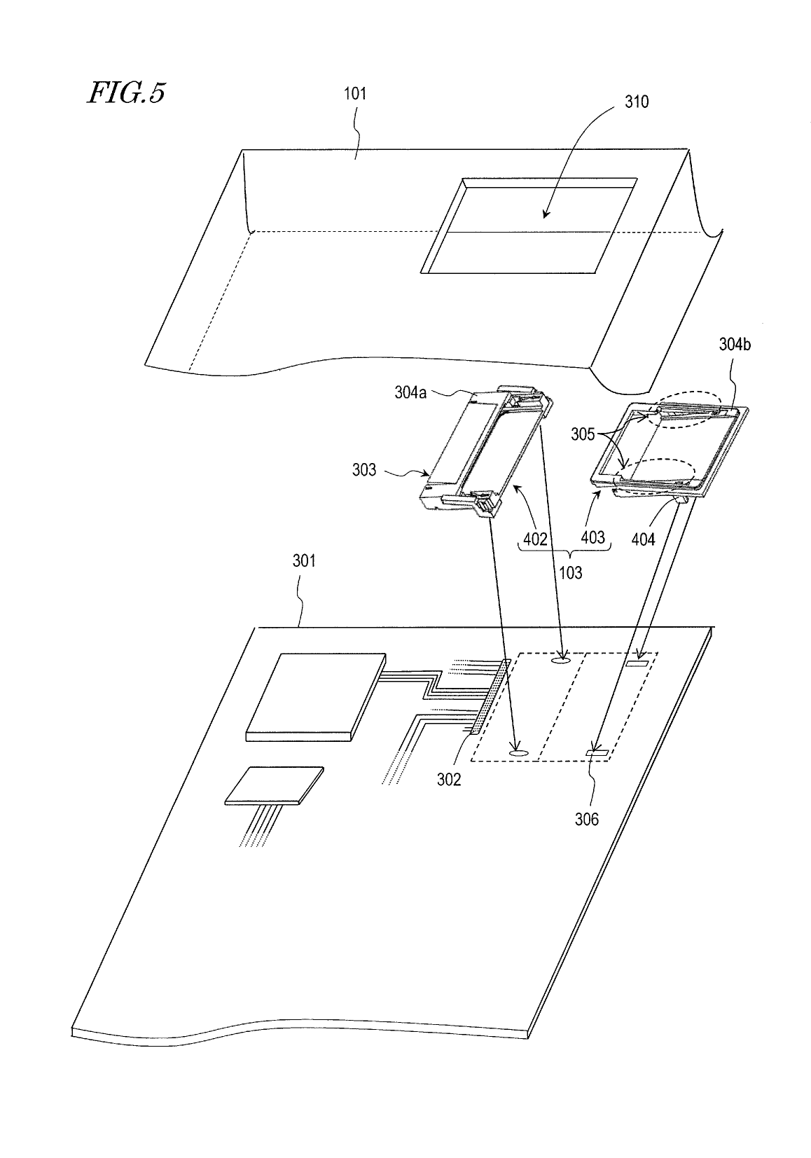

FIG. 4 is a cross-sectional view of the display device 100 into which the external terminal device 200 has been inserted.

The display device 100 includes a board 301 inside. The board 301 may be a printed circuit board, for example, and is covered with the back cover 101 and substantially parallel to the back cover 101. The group of terminals 102 is arranged at one end of the board 301.

As can be seen easily from FIGS. 3B and 4, the external terminal device 200 has been inserted obliquely with respect to the back cover 101. This is because the guide of the connecting slot 103 has guided the external terminal device 200 obliquely with respect to the back cover 101 and holds the external terminal device 200 in that position.

Next, it will be described in detail with reference to FIGS. 5 through 7 exactly what structure the connecting slot 103 may have to get the external terminal device 200 inserted in that way.

FIG. 5 is an exploded perspective view of the connecting slot 103 and other surrounding members. The connecting slot 103 is made up of multiple pieces including at least a first member 402 and a second member 403.

The first member 402 includes the terminal 303 of the connecting slot 103 and a rib 304a. One end of the terminal 303 of the connecting slot 103 is soldered with a line 302 on the board 301, thereby mounting the first member 402 onto the board 301. The other end of the terminal 303 will be connected to the terminal 210 (see FIG. 2) of the external terminal device 200 when the external terminal device 200 is inserted. In this manner, the external terminal device 200 and the board 301 are electrically connected together.

The second member 403 includes a rib 304b and a guide 305. The second member 403 is not soldered onto the board 301. Instead, connecting portions 404 of the second member 403 are fitted into holes 306 that have been cut through the board. In this manner, the second member 403 is mounted onto the board 301. In this case, the second member 403 is arranged adjacent to the first member 402 on the board 301 as if these two members 402 and 403 were integrated together.

Although the first member 402 is supposed to be soldered in this example, soldering is just an exemplary means for establishing electrical connection and any other method may be used as well. Also, no matter whether the first member 402 is soldered or not, connecting portions similar to those 404 of the second member 403 may be provided for the first member 402, too.

Furthermore, there is no need to cut the holes 306 through the board. Alternatively, an edge of the board may be notched and the connecting portions may be fitted into the notched portions.

On an area of the board 301 which is located right under the first and second members 402 and 403 mounted, circuits, chips, elements and other circuit components may be arranged. Naturally, those circuit components should be arranged so as to avoid causing an unnecessary short circuit or placing unnecessary pressure on the chips.

The guide 305 regulates the movable range of the external terminal device 200 so that the external terminal device 200 inserted into the connecting slot 103 defines a predetermined angle with respect to the board 301. For example, the guide 305 may be configured so that when inserted into the connecting slot 103, the external terminal device 200 defines an angle of approximately 7 degrees with respect to the board 301.

It should be noted that this angle is only an example. In this embodiment, a card compliant with the PCMCIA standard is used as an exemplary external terminal device 200. According to the PCMCIA standard, it is recommended that the guide to hold a terminal device have a length (i.e., a guide rail length) of 40 mm or more. On the other hand, as the angle defined by the external terminal device 200 goes closer to zero degrees, it becomes more and more difficult to create a space for mounting other circuit components on the board 301 as will be described later. For that reason, the angle suitably falls within the range of 5 to 9 degrees.

The ribs 304a and 304b may be made of chamfered and molded resin. The periphery of the connecting slot 103 is covered with such ribs 304a and 304b at least partially. As a result, the chances that the user of this display device 100 will cut his or her finger can be reduced.

After the first and second members 402 and 403 have been arranged as the connecting slot 103 on the board 301, the board 301 is capped with the back cover 101 either entirely or just partially. The back cover 101 has an opening 310. The connecting slot 103 is exposed through that opening 310 and is formed in a box shape. In this description, the “box shape” refers to a box that is formed by an insertion slot into which the external terminal device 200 is inserted and side surfaces which cover this connecting slot 103 entirely except the insertion slot. The box corresponds to a recess (space) which is formed by the bottom of the connecting slot 103 and at least one side surface. If the connecting slot 103 has such a box shape, the board 301 is never exposed. As a result, even if any foreign matter such as a coin has happened to enter the connecting slot 103, the foreign matter can go deeper no than the connecting slot 103. Consequently, the chances that the foreign matter will contact with the board 301 can be reduced.

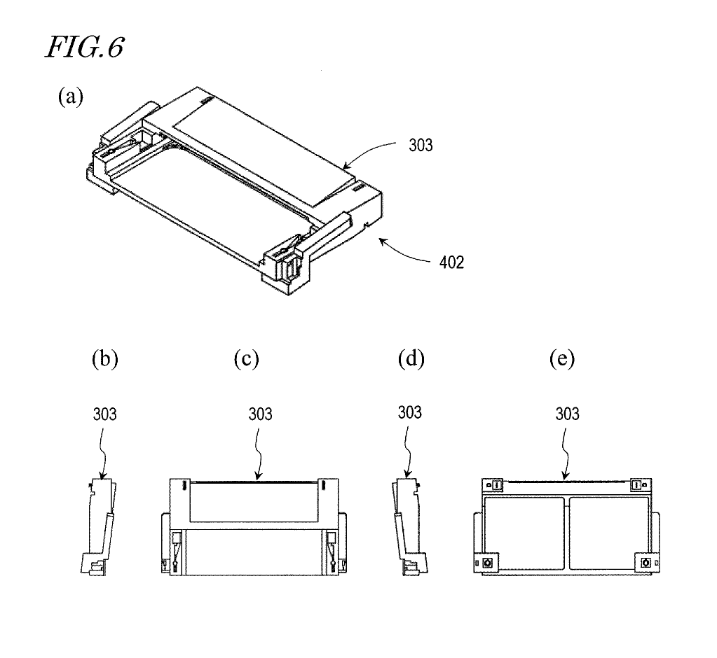

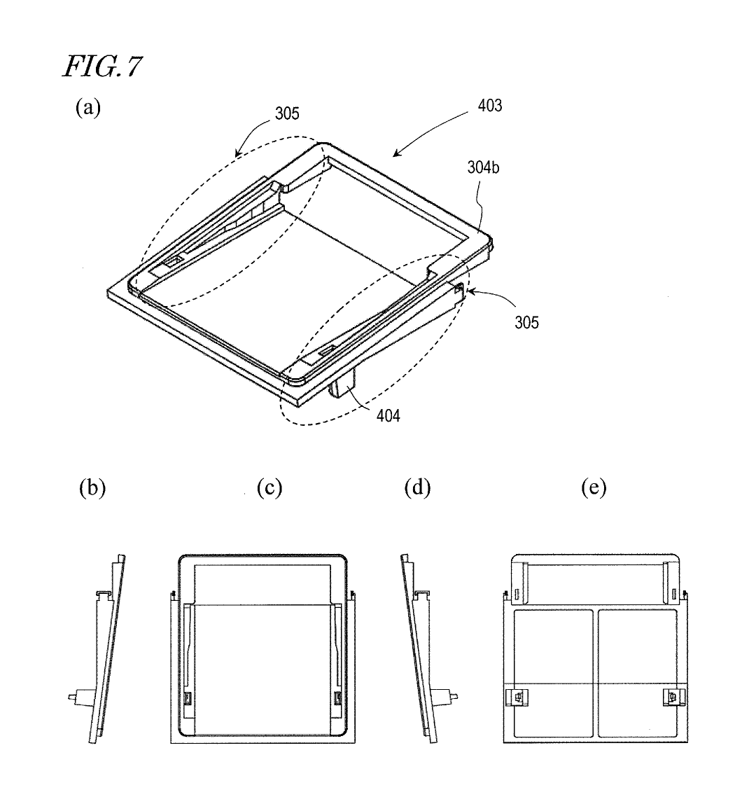

FIG. 6(a) is an enlarged perspective view of the first member 402. FIGS. 6(b), 6(c), 6(d) and 6(e) are respectively a left side view, a top view, a right side view, and a bottom view of the first member 402. In all of these drawings, the position of the terminal 303 of the connecting slot 103 is indicated for your reference.

FIG. 7(a) is an enlarged perspective view of the second member 403. When the second member 403 is arranged on the board 301, the board 301 and the rib 304b become substantially parallel to each other. In order to regulate the direction and angle of insertion of the external terminal device 200, the guide portion 305 of the second member 403 is arranged to define the predetermined angle described above with respect to the rib 304b.

The second member 403 also has connecting portions 404.

The end of the connecting portions 404 is made of an elastically deformable material (such as resin or metal). By fitting the end of the connecting portions 404 into the holes 306 of the board 301, the second member 403 gets mounted onto the board 301. In this manner, the connecting slot 103 can be mounted onto the board 301 stepwise.

More Specifically, by performing a first process step of soldering, the first member 402 gets mounted onto the board 301.

Next, a second process step is performed manually. In this second process step, the connecting portions 404 are fitted into the holes of the board 301. In this manner, the second member 403 can get mounted onto the board 301. If this procedure is followed, circuit components that have been mounted on the board 301 and under the second member 403 can be checked out more easily with the eyes in a testing process step between the first and second process steps while the display device 100 is being assembled. In addition, since the worker can easily remove the second member 403 from the board 301, the circuit components mounted under the second member 403 can be repaired more easily.

FIGS. 7(b), 7(c), 7(d) and 7(e) are respectively a left side view, a top view, a right side view, and a bottom view of the second member 403. As shown in FIG. 7(e), the bottom of the connecting slot 103 has a shape to cover the board 301. In that case, even if the external terminal device 200 has not been inserted into the display device 100 yet, the board 301 is not exposed directly through the connecting slot 103. Thus, the chances that the user of this display device 100 will happen to touch the board 301 by mistake can be reduced.

According to the embodiment described above, there is no need to create a space for housing the external terminal device on the board 301. Since the space that is ordinarily secured for the external terminal device 200 can be eliminated from the board 301, the design process can get done more easily. In addition, since the required area of the board 301 can be reduced, the cost can be cut down, too.

### INDUSTRIAL APPLICABILITY

A display device according to the present invention can be used effectively as a device to which an external terminal device for use to remove a viewing control and for other purposes is attachable.

### REFERENCE SIGNS LIST

100 display device
101 back cover
102 group of terminals
103 connecting slot
104 back cover's first plane
105 back cover's second plane
106 step portion
110 display panel
200 external terminal
301 board
303 connecting slot's terminal
304a, 304b rib
305 guide
402 connecting slot's first member
403 connecting slot's second member

1. A display device comprising:
a display panel;
a board;
a back cover which covers the board at least partially and which has an opening; and
a slot structure which is arranged inside the opening and into which an external terminal device is inserted,
wherein the slot structure includes a guide which holds the external terminal device inserted so that the external terminal device defines a predetermined angle with respect to the board and a terminal which electrically connects the external terminal device to the board.

2. The display device of claim 1, wherein the guide regulates the angle of insertion of the external terminal device so that the external terminal device is inserted at the predetermined angle with respect to the board.

3. The display device of claim 1, wherein if the guide has a length of 40 mm or more, the guide holds the external terminal device so that the external terminal device defines an angle of 5 to 9 degrees with respect to the board.

4. The display device of claim 1, wherein the bottom surface of the slot structure partially covers the board.

5. The display device of claim 4, wherein the slot structure has a box shape which is formed by the bottom surface of the slot structure and side surfaces that cover the slot structure entirely except an insertion slot into which the external terminal device is inserted.

6. The display device of claim 1, wherein the slot structure covers the periphery of the opening at least partially.

7. The display device of claim 1, wherein the slot structure is comprised of a plurality of members including a first member with the terminal and a second member with the guide.

8. The display device of claim 7, wherein the second member has connecting portions for mounting the second member onto the board.

9. The display device of claim 8, wherein an end of the connecting portions is made of an elastically deformable material, and
the second member is mounted onto the board by elastically deforming the respective ends of the connecting portions and fitting the ends into holes or notches that have been cut through the board.

10. The display device of claim 1, wherein the back cover has a first plane and a second plane which is arranged so as to be raised with respect to the first plane,
the opening has been cut through the second plane, and
when the guide holds the external terminal device, the external terminal device is held so as to be housed within the second plane.

11. The display device of claim 10, wherein a terminal receiving a signal from an external device is arranged in a step portion which is located between the first and second planes.
